(19) United States
(12) Patent Application Publication
(10) Pub. No.: US 2005/0139905 A1
(43) Pub. Date: Jun. 30, 2005

(54) Dummy layer in semiconductor device and fabricating method thereof

(75) Inventor: Jin Hyo Jung, Bucheon (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/024,796

(22) Filed: Dec. 30, 2004

(30) Foreign Application Priority Data
Dec. 31, 2003 (KR) 10-2003-0101391

(51) Int. Cl. H01L 29/792

(52) U.S. Cl. 257/326

(57) ABSTRACT

A semiconductor device and fabricating method. The semiconductor device includes a semiconductor substrate, a device isolation layer on the semiconductor substrate in a logic area of the semiconductor device defining at least one dummy active area, a first dummy pattern on the device isolation layer, and a second dummy pattern enclosing the first dummy pattern on the device isolation layer.

### BACKGROUND OF THE INVENTION

1. Field of the Invention

The present invention relates to a dummy layer in a semiconductor device and fabricating method thereof.

2. Discussion of the Related Art

Generally, as design specifications are reduced according to an increasing degree of semiconductor device integration, defects are caused in a pattern while performing photolithography due to an optical proximity effect (OPE) with a neighbor pattern. Specifically, a pattern size in an area where patterns are densely formed densely is smaller than a pattern in an area where patterns are sparsely formed.

As a photoresist pattern is irregularly formed due to OPE, when an area exposed by the photoresist pattern is small (for example, while performing an etch process such as a gate electrode patterning process using the photoresist pattern), an etchant gas fails to be adequately supplied. This results in a variance in an etch rate, which brings about a so-called micro loading effect that results in difficulty in forming a gate electrode pattern. Specifically, the micro loading effect frequently occurs in forming a micro pattern or a contact hole having a high aspect ratio.

In order to minimize the micro loading effect by a conventional process, a dummy pattern and a dummy active area are formed in an area having a relatively low pattern density such as a logic area using the same material of a device provided to a memory cell area having a high pattern density.

A structure of a split gate flash memory device of related art is explained with reference to the drawing as follows.

FIG. 1 is a cross-sectional diagram of a split gate flash memory device according to a related art.

Referring to FIG. 1, a logic area and a memory cell area are defined on a semiconductor substrate 101.

A split gate having first and second gate patterns 104 and 107a is formed on the semiconductor substrate 101 in the memory cell area, and a gate pattern 107b formed of the same material of the second gate pattern 107a is formed on the semiconductor substrate in the logic area.

An insulating layer 105, an ONO (oxide-nitride-oxide) layer 103, and a spacer 106 are provided to a top, bottom and sidewall of the first gate pattern 104, respectively.

The micro loading effect and its solution are explained in detail with reference to the above-configured split gate flash memory device as follows.

In the split gate flash memory device, the memory cell area is a high pattern density area and the logic area is a low pattern density area. Hence, the dummy active area and dummy pattern need to be provided to the logic area to prevent the micro loading effect.

The micro loading effect takes place in forming a high step difference micro pattern or a high aspect ratio contact hole. It is highly probable that the micro loading effect occurs in a logic area having a relatively low pattern density in patterning the material of the first or second gate pattern 104 or 107a having a relatively large thickness among the various elements of the split gate.

In the related art, the dummy active area and the dummy pattern, as shown in FIG. 2 and FIG. 3, are formed on the logic area to prevent the micro loading effect from occurring in the logic area.

FIG. 2 is a layout of a dummy layer according to a related art, and FIG. 3 is a cross-sectional diagram along a cutting line C-C′ in FIG. 2.

Referring to FIG. 2 and FIG. 3, a plurality of dummy active areas 204 are formed with a prescribed interval therebetween, and each of the dummy areas 204 is defined by a field area to have a prescribed size. And, the field area corresponds to a device isolation layer 202. Moreover, a plurality of dummy patterns 203 are formed on the device isolation layer 202 to prevent the micro loading effect in patterning the second gate pattern of the split gate and the gate pattern in the logic area. Each of the dummy patterns 203 is formed of the same material of the second gate of the split gate to have a same height as the second gate.

The related art dummy layer consisting of the dummy patterns and the dummy active areas can minimize the micro loading effect in patterning the second gate pattern of the split gate and the gate pattern in the logic area. And, the related art dummy layer equalizes the step difference in the topography of the substrate when smoothing an insulating interlayer, thereby enhancing the smoothing characteristics.

However, the related art dummy layer fails to prevent the micro loading effect in forming the first gate pattern of the split gate. The first gate pattern of the split gate has a relatively high step difference over the substrate, similar to that of the second gate pattern, thereby triggering the micro loading effect on the logic area on patterning the first gate pattern.

### SUMMARY OF THE INVENTION

Accordingly, the present invention is directed to a dummy layer in a semiconductor device and fabricating method thereof that substantially obviates one or more problems due to limitations and disadvantages of the related art.

The present invention advantageously provides a dummy layer in a semiconductor device and fabricating method thereof, by which a micro loading effect of a logic area is minimized in fabricating a split gate flash memory device.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a dummy layer in a semiconductor device according to the present invention includes a semiconductor substrate, a device isolation layer on the semiconductor substrate in a logic area of the semiconductor device to define at least one dummy active area, a first dummy pattern on the device isolation layer, and a second dummy pattern enclosing the first dummy pattern on the device isolation layer.

In an exemplary embodiment, the semiconductor device is a split gate flash memory device having a first gate pattern and a second gate pattern.

In an exemplary embodiment, the first and second dummy patterns are formed of same materials as the first and second gate patterns, respectively.

In an exemplary embodiment, the first and second dummy patterns are formed to have about equal heights as the first and second gate patterns, respectively.

In an exemplary embodiment, a width difference between the first and second dummy patterns is about 0.5 to about 1 μm.

In another aspect of the present invention, a method of fabricating a dummy layer in a semiconductor device includes the steps of forming a device isolation layer on a semiconductor substrate in a logic area of the semiconductor device to define at least one dummy active area, forming a first dummy pattern on the device isolation layer, and forming a second dummy pattern enclosing the first dummy pattern on the device isolation layer.

In an exemplary embodiment, the semiconductor device is a split gate flash memory device having a first gate pattern and a second gate pattern.

In an exemplary embodiment, the first and second dummy patterns are formed of same materials as the first and second gate patterns, respectively.

In an exemplary embodiment, the first and second dummy patterns are formed to have about equal heights as the first and second gate patterns, respectively.

In an exemplary embodiment, a width difference between the first and second dummy patterns is about 0.5 to about 1 μm.

It is to be understood that both the foregoing general description and the following detailed description of the present invention are exemplary, but are not restrictive of the invention.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional diagram of a split gate flash memory device according to a related art;

FIG. 2 is a layout of a dummy layer according to a related art;

FIG. 3 is a cross-sectional diagram along a cutting line C-C′ in FIG. 2;

FIG. 4 is a layout of a dummy layer according to the present invention;

FIG. 5 is a cross-sectional diagram along a cutting line A-A′ in FIG. 4;

FIG. 6 is a cross-sectional diagram along a cutting line B-B′ in FIG. 4; and

FIGS. 7A to 7C are cross-sectional diagrams for explaining a method of fabricating a dummy layer in a semiconductor device according to the present invention.

### DETAILED DESCRIPTION OF THE INVENTION

Reference will now be made in detail to exemplary embodiments of the present invention, which are illustrated in the accompanying drawings. Wherever possible, the same reference numbers will be used throughout the drawings to refer to the same or like parts.

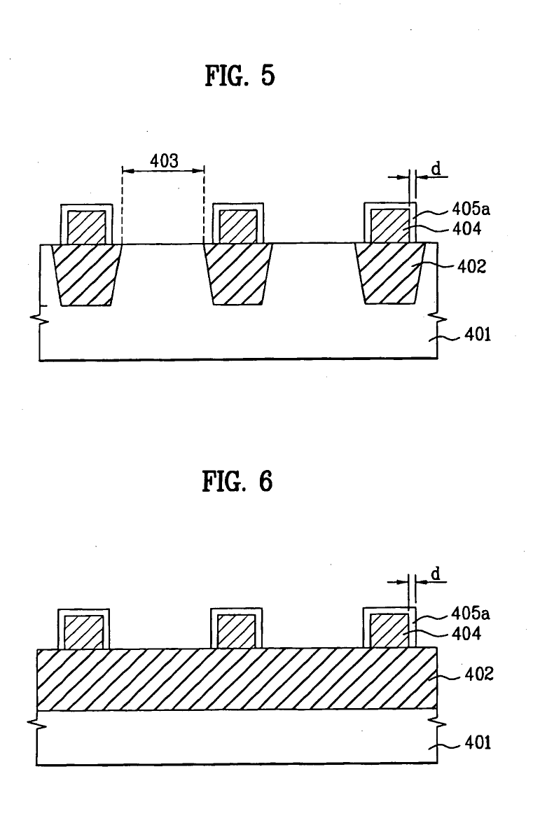

FIG. 4 is a layout of a dummy layer according to an embodiment of the present invention, FIG. 5 is a cross-sectional diagram along a cutting line A-A′ in FIG. 4, and FIG. 6 is a cross-sectional diagram along a cutting line B-B′ in FIG. 4.

A dummy layer is formed in a logic area of a split gate flash device, for example. However, the present invention is applicable to an area having a low pattern density in any other kind of semiconductor device.

Referring to FIG. 4, in a dummy layer 400 of a semiconductor device according to the present invention, a plurality of dummy active areas 403 are isolated from each other on a semiconductor substrate. Each of the dummy active areas 403 is defined by a device isolation layer 402 to occupy a prescribed area and may have a shape such as a polygon, a circle, or the like.

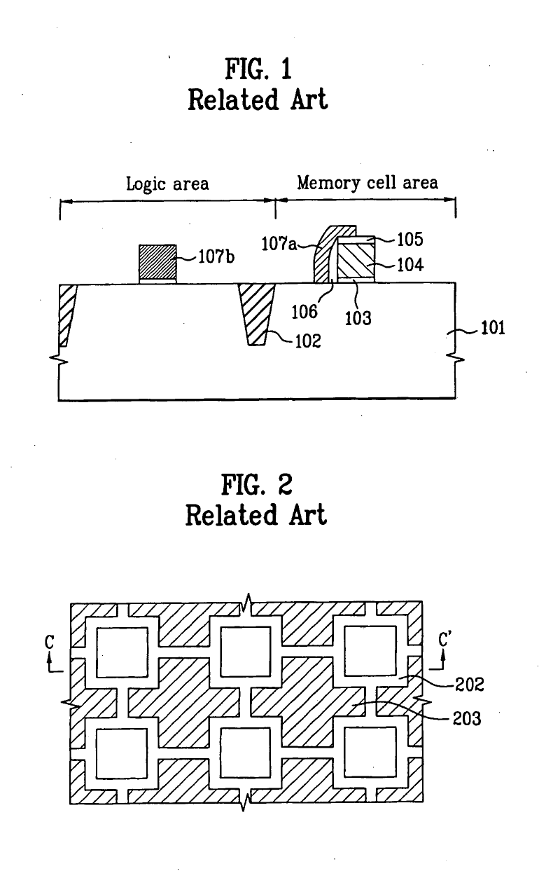

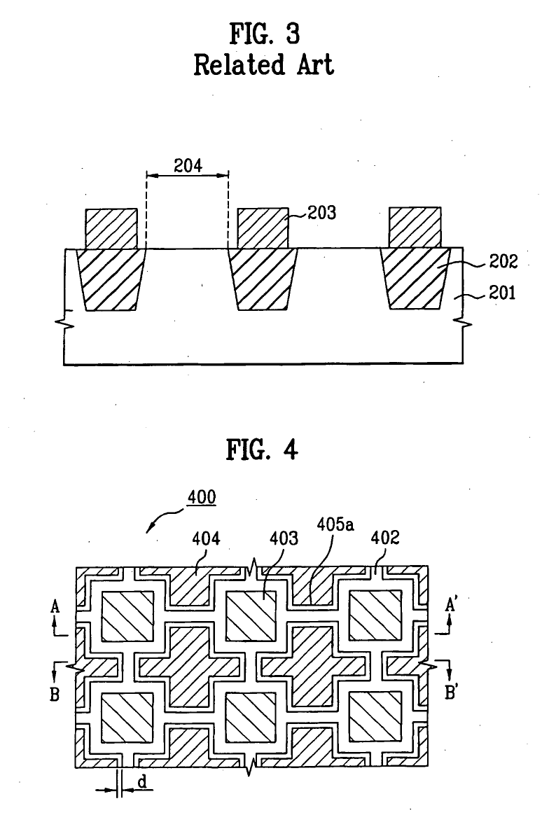

A cross type first dummy pattern 404 and a cross type second dummy pattern 405a are provided within a space between the dummy active areas 403. An occupied area of the first dummy pattern 404 is equal to or smaller than that of the second dummy pattern area 405a. The first dummy pattern 404 may be formed of the same material of a first gate pattern configuring the split gate in FIG. 1 to have the same height of the first gate pattern. The second dummy pattern 405a may be formed of the same material of a second gate pattern configuring the split gate in FIG. 1 to have the same height of the second gate pattern.

Each width of the first and second dummy patterns 404 and 405a is variable according to a design rule of the first and second gate patterns. A width difference between the first and second dummy patterns 404 and 405a is between about 0.5 to about 1.0 μm.

FIG. 5 is a cross-sectional diagram along a cutting line A-A′ in FIG. 4.

Referring to FIG. 5, the device isolation layer 402 defining the active area 403 is formed on the semiconductor substrate 401. The first dummy pattern 404 is formed on the device isolation layer 402, and the second dummy pattern 405a encloses the first dummy pattern 404. In one embodiment, the second dummy pattern 405a is located a prescribed distance from the dummy active area 403, such that second dummy pattern 405a is not shorted to the dummy active area 403.

FIG. 6 is a cross-sectional diagram along a cutting line B-B′ in FIG. 4, in which a cross-section of the device isolation layer 402 between the dummy active areas 403 is shown.

Referring to FIG. 6, a plurality of the first dummy patterns 404 equal to each other in length are repeatedly formed on the device isolation layer 402 at a prescribed interval from each other. A plurality of the second dummy patterns 405a encloses a plurality of the first dummy patterns 404, respectively.

A method of fabricating a dummy layer in a semiconductor device according to the present invention is explained as follows.

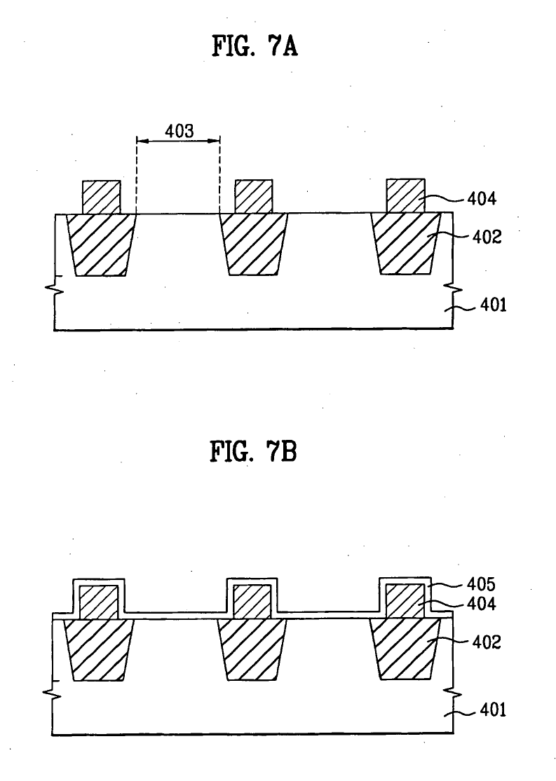

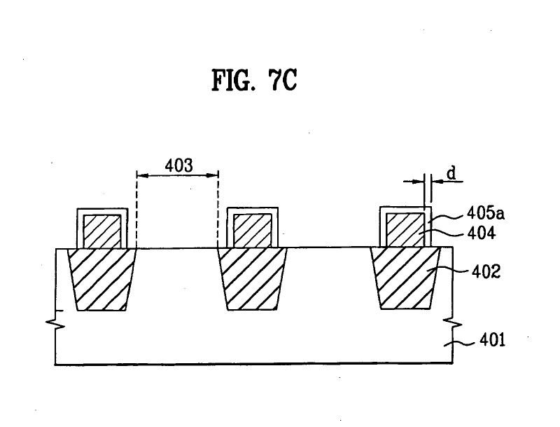

FIGS. 7A to 7C are cross-sectional diagrams for explaining a method of fabricating a dummy layer in a semiconductor device according to the present invention.

Referring to FIG. 7A, a device isolation layer 402 is formed on a field area of a semiconductor substrate 401 by a device isolation process such as STI (shallow trench isolation) or the like to define a plurality of dummy active areas 403 of the semiconductor substrate 401 formed of single crystalline silicon or the like. The area where the dummy active areas 403 are formed corresponds to an area having low density of patterns, such as gate electrodes or the like. For instance, the area having the dummy active areas 403 formed thereon corresponds to a logic area of a split gate flash memory device.

A first conductor layer is deposited on the substrate 401. The first conductor layer corresponds to a first gate pattern forming material of the split gate flash memory device, for example. Hence, the first conductor layer is deposited to have about the same height of the first gate pattern forming material.

The first conductor layer is selectively patterned by photolithography to simultaneously form a first dummy pattern 404 on the device isolation layer 402 and a first gate pattern. A width of the first dummy pattern 404 is adjustable according to a design rule of the first gate pattern.

Referring to FIG. 7B, a second conductor layer 405 is deposited over the substrate 401 including the first dummy pattern 404. The second conductor layer 405 corresponds to a second gate pattern forming material of the split gate flash memory device, for example. Hence, the second conductor layer 405 is deposited to have about the same height as the second gate pattern forming material.

Referring to FIG. 7C, the second conductor layer 405 is selectively patterned to form a second dummy pattern 405a covering the first dummy pattern 404 on the device isolation layer 402. The second dummy pattern 405a is formed to enclose the first dummy pattern 404. A second gate pattern of the split gate is formed while forming the second dummy pattern 405a.

The second dummy pattern 405a is formed at a prescribed distance from the dummy active area 403, such that second dummy pattern 405a is not shorted with the dummy active area 403. A width difference between the first and second dummy patterns 404 and 405a is about 0.5 to about 1.0 μm.

Accordingly, in the present invention, the first and second dummy patterns are formed on the logic area of the split gate flash memory to correspond to the first and second gate patterns of the split gate, whereby the micro loading effect can be minimized in the logic area.

Korean Patent Application No. P2003-0101391, filed on Dec. 31, 2003, is hereby incorporated by reference in its entirety.

It will be apparent to those skilled in the art that various modifications and variations can be made in the present invention. Thus, it is intended that the present invention covers the modifications and variations of this invention within the scope of the appended claims and their equivalents.

1. A dummy layer in a semiconductor device, comprising:
a semiconductor substrate;
a device isolation layer on the semiconductor substrate in a logic area of the semiconductor device defining at least one dummy active area;
a first dummy pattern on the device isolation layer; and
a second dummy pattern enclosing the first dummy pattern on the device isolation layer.

2. The dummy layer of claim 1, wherein the semiconductor device is a split gate flash memory device having a first gate pattern and a second gate pattern.

3. The dummy layer of claim 2, wherein the first and second dummy patterns are formed of same materials of the first and second gate patterns, respectively.

4. The dummy layer of claim 2, wherein the first and second dummy patterns are formed to have about equal heights as the first and second gate patterns, respectively.

5. The dummy layer of claim 1, wherein a width difference between the first and second dummy patterns is about 0.5 to about 1 μm.

6. A method of fabricating a dummy layer in a semiconductor device, comprising the steps of:
forming a device isolation layer on a semiconductor substrate in a logic area of the semiconductor device to define at least one dummy active area;
forming a first dummy pattern on the device isolation layer; and
forming a second dummy pattern enclosing the first dummy pattern on the device isolation layer.

7. The method of claim 6, wherein the semiconductor device is a split gate flash memory device having a first gate pattern and a second gate pattern.

8. The method of claim 7, wherein steps of forming a first dummy pattern and forming a second dummy pattern include forming the first and second dummy patterns of same materials as the first and second gate patterns, respectively.

9. The method of claim 7, wherein steps of forming a first dummy pattern and forming a second dummy pattern include forming the first and second dummy patterns to have about equal heights as the first and second gate patterns, respectively.

10. The method of claim 6, wherein a width difference between the first and second dummy patterns is about 0.5 to about 1 μm.

11. A method of fabricating a dummy layer in a semiconductor device, comprising:
a step for forming a device isolation layer on a semiconductor substrate in a logic area of the semiconductor device to define at least one dummy active area;
a step for forming a first dummy pattern on the device isolation layer; and
a step for forming a second dummy pattern enclosing the first dummy pattern on the device isolation layer.

12. The method of claim 11, wherein the semiconductor device is a split gate flash memory device having a first gate pattern and a second gate pattern.

13. The method of claim 12, wherein the steps for forming a first dummy pattern and forming a second dummy pattern include steps for forming the first and second dummy patterns of same materials as the first and second gate patterns, respectively.

14. The method of claim 12, wherein the steps for forming a first dummy pattern and forming a second dummy pattern include steps for forming the first and second dummy patterns to have about equal heights as the first and second gate patterns, respectively.

15. The method of claim 11, wherein a width difference between the first and second dummy patterns is about 0.5 to about 1 μm.
